(19) United States
(12) Patent Application Publication
(10) Pub. No.: US 2018/0254186 A1
(43) Pub. Date: Sep. 6, 2018

(54) METHOD FOR MANUFACTURING SEMICONDUCTOR DEVICE AND APPARATUS FOR MANUFACTURING SAME

(71) Applicant: Kabushiki Kaisha Toshiba, Tokyo (JP)

(72) Inventors: Tomohiro Nitta, Himeji Hyogo (JP); Toshihide Shinmei, Shiso Hyogo (JP)

(21) Appl. No.: 15/690,749

(22) Filed: Aug. 30, 2017

(30) Foreign Application Priority Data
Mar. 3, 2017 (JP) 2017-040453

(51) Int. Cl. H01L 21/04; H01L 29/45; C23C 14/48; H01J 37/317; C23C 14/04

(52) U.S. Cl. CPC H01L 21/0465; H01L 21/0485; H01L 29/45; H01J 2237/31701; H01J 37/3171; C23C 14/042; C23C 14/48

(57) ABSTRACT

A method for manufacturing a semiconductor device includes introducing a group III element to a part of a substrate containing silicon and carbon; introducing oxygen into the part of the substrate; and heating the substrate after introducing the Group III element and the oxygen.

### CROSS-REFERENCE TO RELATED APPLICATIONS

This application is based upon and claims the benefit of priority from Japanese Patent Application No. 2017-040453, filed on Mar. 3, 2017; the entire contents of which are incorporated herein by reference.

### FIELD

Embodiments relate to a method for manufacturing a semiconductor device and an apparatus for manufacturing the same.

### BACKGROUND

In recent years, it has been proposed to use a silicon carbide (SIC) substrate as a substrate of a power control semiconductor device, since SiC has a bandgap wider than a bandgap of silicon, and provides higher breakdown voltage. It is also required for the SiC substrate to achieve ohmic connection, when a conductive member such as a contact material and an electrode is electrically connected thereto.

### BRIEF DESCRIPTION OF THE DRAWINGS

FIG. 1 is a view showing an apparatus for manufacturing a semiconductor device according to a first embodiment;

FIGS. 2A to 2E are cross-sectional views showing a method for manufacturing a semiconductor device according to the first embodiment;

FIG. 3 is a view showing a crystal structure of a p-type ohmic layer in the first embodiment;

FIG. 4 is a view showing a crystal structure of a p-type ohmic layer in a comparative example; and

FIGS. 5A to 5E are cross-sectional views showing a method for manufacturing a semiconductor device according to a second embodiment.

### DETAILED DESCRIPTION

According to one embodiment, a method for manufacturing a semiconductor device includes: introducing a group III element to a part of a substrate containing silicon and carbon; introducing oxygen into the part of the substrate; and heating the substrate after introducing the Group III element and the oxygen.

According to another embodiment, an apparatus for manufacturing a semiconductor device includes: an ion source for generating an ion of a group III element or a group V element, and an ion of oxygen; a mass analyzer for selecting each of the ions; an accelerator for accelerating the ions; and a chamber for accommodating a material. The ions are injected into the material.

### First Embodiment

The first embodiment will be described below.

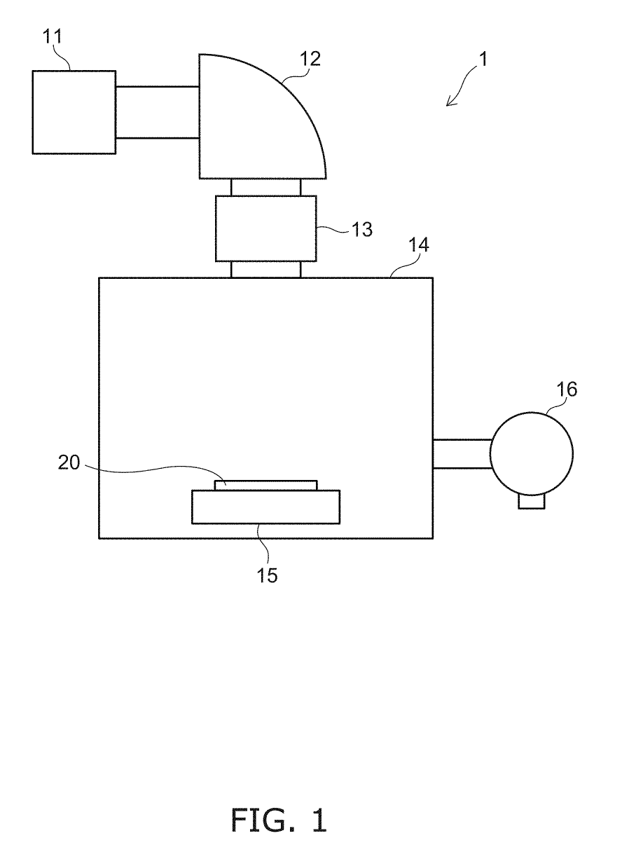

FIG. 1 is a view showing an apparatus for manufacturing a semiconductor device according to the embodiment.

As shown in FIG. 1, the manufacturing apparatus 1 of the semiconductor device according to the embodiment is an ion-implantation apparatus.

In the manufacturing apparatus 1, an ion source 11 for generating ions, a mass analyzer 12 for selecting an ion based on a mass thereof, an accelerator 13 for accelerating the ion, a chamber 14 into which the accelerated ion is introduced, a heating unit 15, and an vacuum pumping means 16 for evacuating the inside of the chamber 14 are provided.

The elements are ionized in the ion source 11. The elements ionized in the manufacturing apparatus 1 include the group III elements (i.e. the group 13 elements) and oxygen (O). The group III elements are boron (B), aluminum (Al), gallium (Ga), indium (In), thallium (TI), and the like.

The ion source 11, the mass analyzer 12, the accelerator 13, and the chamber 14 are spatially connected in this order. Thereby, the ions generated in the ion source 11 are selected by the mass analyzer 12, accelerated to a predetermined energy level in the accelerator 13, and then introduced into the chamber 14.

A material to be implanted is loaded in the chamber 14. In the embodiment, the material to be implanted is a silicon carbide (SiC) substrate 20. At least a part of the heating means 15 is disposed in the chamber 14. The heating means 15 can hold and heat the material up to a temperature of not less than 250° C. and not more than 500° C., for example. The vacuum pumping means 16 can exhaust a gas in the chamber 14, and evacuate the inside of the chamber 14.

A method for manufacturing a semiconductor device according to the embodiment will be described below.

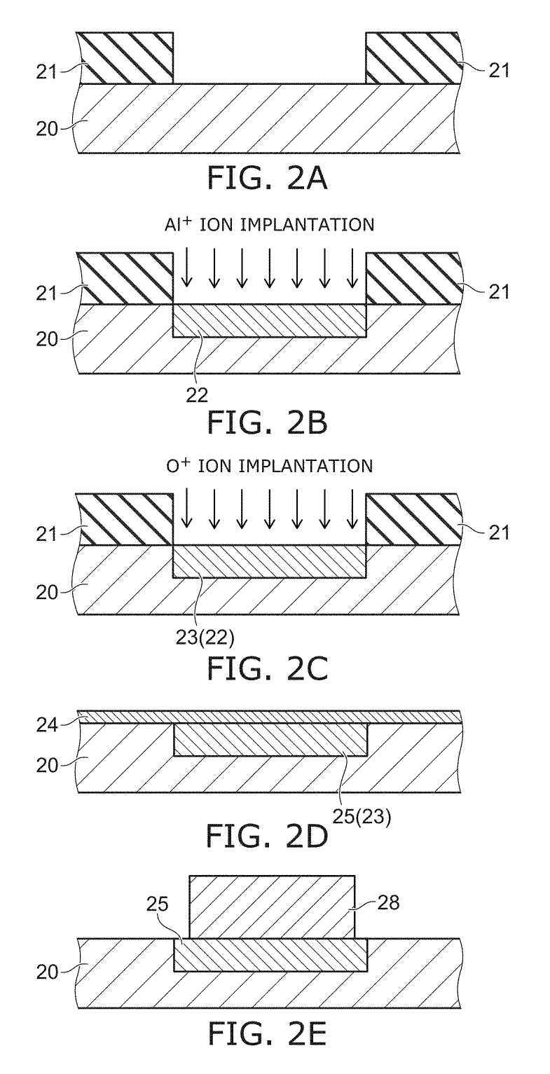

FIGS. 2A to 2E are cross-sectional views showing a manufacturing method for the semiconductor device according to the embodiment.

The manufacturing method for the semiconductor device according to the embodiment includes the operation of the manufacturing apparatus according to the embodiment.

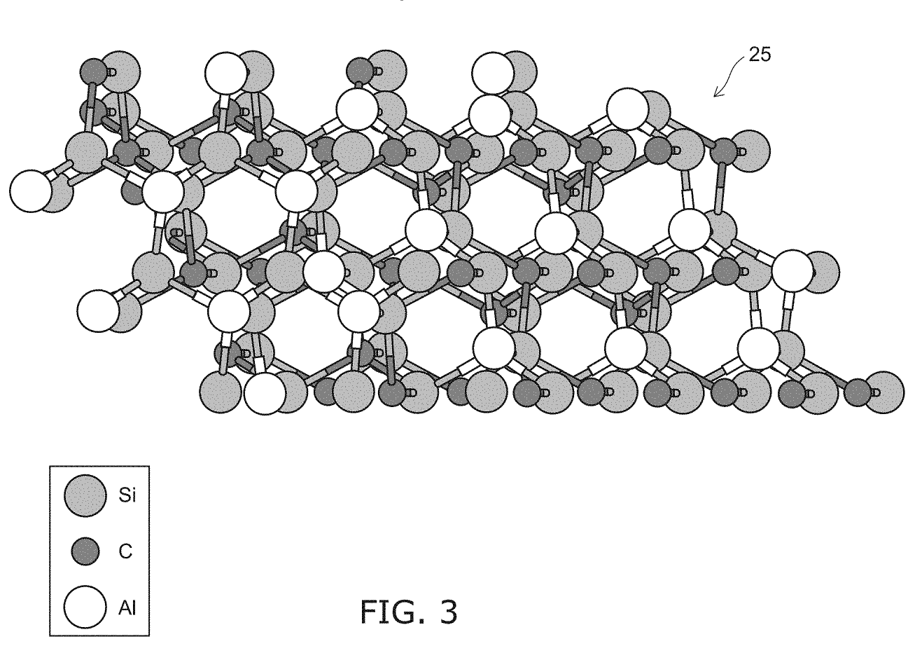

FIG. 3 is a view showing a crystal structure of a p-type ohmic layer in the embodiment.

First, as shown in FIG. 2A, a SIC substrate 20 is prepared. The SIC substrate 20 is, for example, a wafer of monocrystalline silicon carbide. Then, a mask material 21 is formed on the SiC substrate 20. The mask material 21 is patterned into a predetermined shape, and includes a region opened to form a p-type ohmic layer.

Then, as shown in FIG. 1 and FIG. 2B, the SIC substrate 20 is loaded in the chamber 14 of the manufacturing apparatus 1, and held by the heating means 15. Subsequently, the vacuum pumping means 16 exhausts the gas in the chamber 14 to evacuate the inside thereof. Further, the heating means 15 heats the SIC substrate 20 to be in a temperature range of not less than 250° C. and not more than 500° C. The temperature of the SIC substrate 20 is, for example, 500° C.

Under these conditions, aluminum ions are generated in the ion source 11 of the manufacturing apparatus 1, selected by the mass analyzer 12, accelerated in the accelerator 13, introduced into the chamber 14 and caused to reach the SIC substrate 20. Thereby, the aluminum ions are implanted into a portion of the SiC substrate 20 that is not covered with the mask material 21.

The ion implantation is performed under the acceleration voltage of, for example, not less than 15 keV and not more than 45 key, for example, 40 keV, and the dose amount of, for example, not less than 3×10¹⁴ cm⁻² and not more than 2×10¹⁵ cm⁻², for example, 1×10¹⁵ cm⁻². Thereby, an aluminum containing layer 22 is formed in a part of the top portion of the SIC substrate 20. The aluminum containing layer 22 has a depth of, for example, not less than 10 nm (nanometer) and not more than 100 nm, for example, not less than 30 nm and not more than 40 nm, for example, 40 nm. The aluminum containing layer 22 includes aluminum atoms with a concentration of 1×10²° cm⁻³, for example.

Then, as shown in FIG. 1 and FIG. 2C, while the heating means 15 heats the SIC substrate 20, oxygen ions are generated in the ion source 11, selected by the mass analyzer 12, accelerated in the accelerator 13, introduced into the chamber 14, and caused to reach the SiC substrate 20. Thereby, oxygen ions are implanted into a portion of the SiC substrate 20 that is not covered with the mask material 21, i.e. into the aluminum containing layer 22.

This ion implantation is performed under the acceleration voltage of, for example, not less than 15 key and not more than 45 keV, for example, 40 key, and the dose amount of, for example, not less than 0.1 times and not more than 1 time the dose amount of aluminum ions. Thereby, the aluminum-containing layer 22 is converted to an aluminum-oxygen containing layer 23. The aluminum-oxygen containing layer 23 has a depth substantially same as the depth of the aluminum-containing layer 22, and includes oxygen atoms with the concentration of, for example, not less than 1×10¹⁹ cm⁻³ and not more than 1×10²⁰ cm⁻³. Thereafter, the SiC substrate 20 is unloaded from the chamber 14, and then, the mask material 21 is removed.

Then, as shown in FIG. 2D, a resist (not shown) is applied to the top surface of the SiC substrate 20, and heated up to, for example, 1000° C. to form a cap film 24 containing carbon as a main component. Subsequently, a heat treatment is applied to the SiC substrate 20 with the cap film 24 attached thereto. This heat treatment is performed, for example, under the temperature of not less than 1600° C., for example, not less than 1700° C. and not more than 1900° C., and the heating time is set to not more than 10 minutes, for example.

Thereby, as shown in FIG. 2D and FIG. 3, a carbon atom of the SiC substrate 20 is replaced with an aluminum atom in the aluminum-oxygen containing layer 23; and the aluminum atom is bonded with the silicon atom, and activated as an acceptor. A carbon atom substituted with the aluminum atom and separated from the silicon atom is bonded with an oxygen atom in the aluminum-oxygen containing layer 23, forming carbon dioxide (CO₂) or carbon monoxide (CO), and being released from the SiC substrate 20. Moreover, an aluminum atom is more likely to bond with a silicon atom because the carbon atom is released. As a result, the aluminum-oxygen containing layer 23 becomes a p-type ohmic layer 25. The p-type ohmic layer 25 includes few single carbon atoms separated from silicon atoms and also, few aluminum atoms not bonded to silicon atoms. The p-type ohmic layer 25 is exposed in the top surface of the SiC substrate 20, and has a depth of, for example, not less than 10 nm and not more than 100 nm, for example, 30 nm to 40 nm, for example, 40 nm.

Then, as shown in FIG. 2E, the cap film 24 is removed. Then, a conductive member 28 is formed on the p-type ohmic layer 25. The conductive member 28 is made of a conductive material, for example, metal material such as nickel silicide (NiSi). The conductive member 28 is, for example, a contact material or an electrode. At this time, the conductive member 28 is in ohmic contact with the p-type ohmic layer 25. In this manner, the semiconductor device according to the embodiment is manufactured.

Effects of the embodiment will be described below.

In the embodiment, aluminum atoms and oxygen atoms are introduced into the same part of the SiC substrate 20 in the steps shown in FIGS. 2B and 2C, and the heat treatment is performed in the step shown in FIG. 2D. Thereby, a part of the carbon atoms contained in the SIC substrate 20 is released as the carbon dioxide or carbon monoxide from the SIC substrate 20.

Thereby, as shown in FIG. 3, the concentration of the single carbon atoms separated from the silicon atoms decreases in the p-type ohmic layer 25. Moreover, since the aluminum-oxygen containing layer 23 turn out to have silicon-rich composition by releasing the carbon atoms, an aluminum atom is likely to enter the vacant carbon site, and the concentration of aluminum atoms decreases, which are not bonded to silicon atoms. Thus, the activation rate of aluminum atoms is improved, and the resistivity is decreased in the p-type ohmic layer 25. Thereby, it is possible to reduce the resistance between the p-type ohmic layer 25 and the conductive member 28. As a result, a high-performance semiconductor device can be manufactured.

In the embodiment, oxygen atoms are introduced into the SiC substrate 20 using ion implantation in the step shown in FIG. 2C. Thereby, the oxygen atoms can be introduced into substantially the entire aluminum containing layer 22, and the substantially entire aluminum containing layer 22 can be converted to the aluminum-oxygen containing layer 23. As a result, in the step shown in FIG. 2D, the substantially entire aluminum-oxygen containing layer 23 can be converted to the p-type ohmic layer 25 by performing a heat treatment. In this manner, it is possible to effectively use the aluminum atoms implanted into the SIC substrate 20.

It should be noted that the aluminum ion implantation shown in FIG. 2B and the oxygen ion implantation shown in FIG. 2C are preformed in no particular order. That is, although the embodiment shows an example where oxygen atoms are ion-implanted after the aluminum ion-implantation, aluminum atoms may be ion-implanted after the oxygen ion implantation. Moreover, the group III element to be ion-implanted is not limited to aluminum, and may be boron, gallium, indium, thallium, or the like. Further, the material of the conductive member 28 is not limited to nickel silicide, but may be, for example, titanium (Ti), aluminum (Al), or silicide thereof. Other metal material and silicide thereof may also be used.

### COMPARATIVE EXAMPLE

A comparative example will be described below.

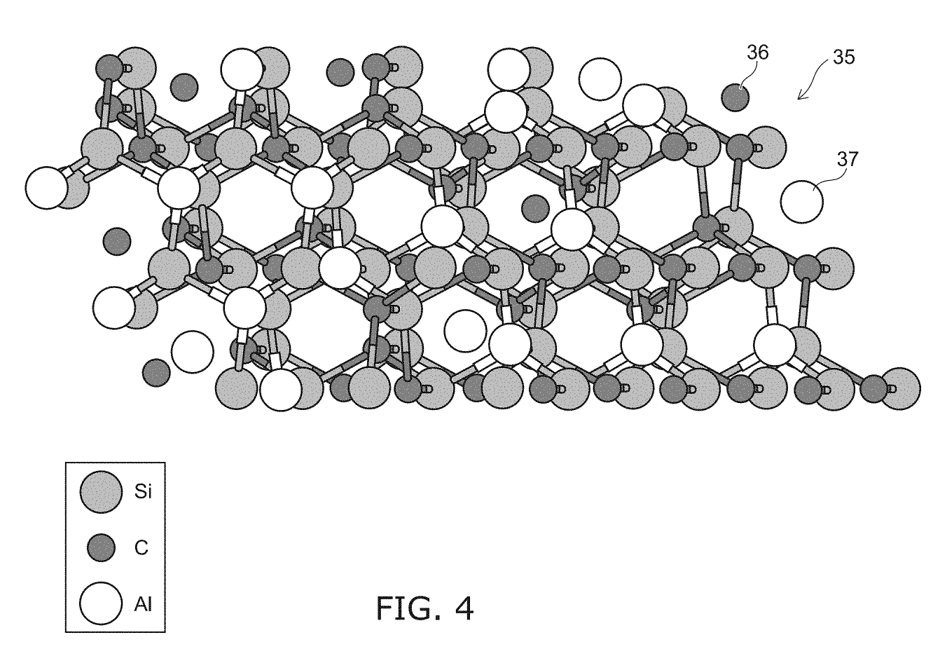

FIG. 4 is a view showing the crystal structure of a p-type ohmic layer in the comparative example.

Compared with the first embodiment, the oxygen ion implantation shown in FIG. 2C is not performed in the comparative example. That is, only aluminum atoms are ion-implanted into the p-type ohmic layer of the SiC substrate 20.

As a result, as shown in FIG. 4, there are many carbon atoms 36 not bonded to silicon atoms and aluminum atoms 37 not bonded to silicon atoms in the p-type ohmic layer 35 in the comparative example. Since aluminum atoms not bonded to silicon atoms are difficult to activate, the activation rate of the implanted aluminum atoms is lower. Accordingly, the resistivity is higher in the p-type ohmic layer 35 of the comparative example. The resistivity is also increased due to carbon atoms 36 that are separated from the silicon atoms and remain in the p-type ohmic layer 35. Thus, when a conductive member (not shown) is formed on the p-type ohmic layer 35 and is in the ohmic-connection with the p-type ohmic layer 35, the resistance between the p-type ohmic layer 35 and the conductive member becomes higher, and the operation speed of the semiconductor device becomes lower.

In contrast, in the first embodiment described above, a part of the carbon atoms in the SiC substrate is removed by the ion-implanted oxygen atoms. Thereby, the ion-implanted aluminum atoms easily bond with the silicon atoms, and the activation rate of aluminum improves. Also, the carbon atoms separated from silicon atoms are removed from the p-type ohmic layer. Thus, the resistivity of the p-type ohmic layer is lower.

### Second Embodiment

A second embodiment will be described below. An apparatus for manufacturing a semiconductor device according to the embodiment is the same as the manufacturing apparatus 1 shown in FIG. 1. However, the ion source 11 can ionize a group V element (a group 15 element) and oxygen. Group V elements (i.e. Group 15 elements) are phosphorus (P), nitrogen (N), arsenic (As), and the like.

A method for manufacturing the semiconductor device according to the embodiment will be described below.

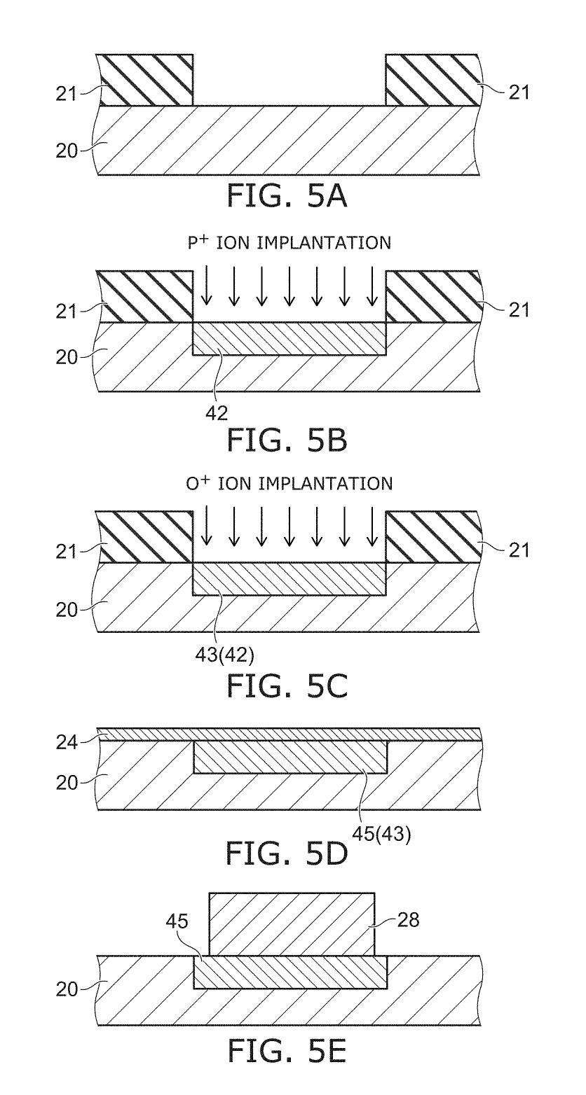

FIGS. 5A to 5E are cross-sectional views showing the manufacturing method for the semiconductor device according to the embodiment.

In the following description that the parts same as those in the first embodiment described above will be briefly explained or omitted.

First, as shown in FIG. 5A, a SiC substrate 20 is prepared and a mask material 21 is formed on the SIC substrate 20. The mask material 21 includes a region opened to form an n-type ohmic layer.

Then, as shown in FIG. 1 and FIG. 5B, the SiC substrate 20 is loaded in the chamber 14 of the manufacturing apparatus 1. Subsequently, the vacuum pumping means 16 evacuates the inside of the chamber 14 and the heating means 15 heats the SiC substrate 20 to a temperature, for example, in a range of not less than 250° C. and not more than 500° C.

Under these conditions, phosphorus ions are generated in the ion source 11, selected by the mass analyzer 12, and accelerated in the accelerator 13, reaching the SIC substrate 20. As a result, phosphorus is ion-implanted into a portion of the SIC substrate not covered with the mask material 21.

This ion implantation is performed for example under the dose amount of not less than 3×10¹³ cm⁻² and not more than 2×10¹⁵ cm⁻², for example, 1×10¹⁴ cm⁻². The lower limit value of the preferable range of the dose amount is lower than the lower limit value (3×10¹⁴ cm⁻²) of the preferable range of the dose amount of aluminum ions in the first embodiment aforementioned. This is because the donor can provide the ohmic state in the semiconductor material, which is the base material, at a concentration lower than that of the acceptor. Moreover, this ion implantation is performed under an acceleration voltage same as that in the first embodiment, for example, not less than 15 keV and not more than 45 keV, for example, 40 keV.

Thereby, a phosphorus containing layer 42 is formed in a part of the top portion of the SiC substrate 20. The phosphorus containing layer 42 has, for example, a depth of not less than 10 nm and not more than 100 nm, for example, 30 to 40 nm, for example, 40 nm.

Then, as shown in FIG. 5C, oxygen is ion-implanted into a portion of the SiC substrate 20 which is not covered with the mask material 21, that is, into the phosphorus containing layer 42. This ion implantation is performed, for example, under an acceleration voltage of not less than 15 keV and not more than 45 keV, for example, 40 keV, and a dose amount of not less than 0.1 times and not more than 1 time the dose amount of phosphorus ions. Thereby, the phosphorus containing layer 42 is converted to a phosphorus-oxygen containing layer 43.

Then, as shown in FIG. 5D, a cap film 24 is formed on the top surface of the SiC substrate 20. Subsequently, heat treatment is performed on the SiC substrate 20. The heat treatment is performed under the conditions same as that in the first embodiment mentioned above, for example, a temperature of not less than 1600° C., for example, not less than 1700° C. and not more than 1900° C., and the heating time set to not more than 10 minutes, for example.

Thereby, a carbon atom of the SiC substrate 20 is substituted with the phosphorus atom in the phosphorus-oxygen containing layer 43. The phosphorus atom forms bond with a silicon atom, and is activated as a donor. On the other hand, the carbon atom substituted with the phosphorus atom and separated from the silicon atom is bonded with oxygen atoms in the phosphorus-oxygen containing layer 43 to form carbon dioxide (CO₂) or carbon monoxide (CO), and is released from the SIC substrate 20. As a result, the phosphorus-oxygen containing layer 43 is converted to the n-type ohmic layer 45.

In the n-type ohmic layer 45, there are few single carbon atoms separated from silicon atoms, and there are also few phosphorus atoms not bonded to silicon atoms. The n-type ohmic layer 45 is exposed in the top surface of the SIC substrate 20, and has a depth of not less than 10 nm and not more than 100 nm, for example, 30 nm to 40 nm, for example, 40 nm.

Then, as shown in FIG. 5E, the cap film 24 is removed, and a conductive member 28 made of a conductive material, for example, a metal material such as nickel silicide (NiSi) is formed on the n-type ohmic layer 45. At this time, the conductive member 28 is in ohmic contact with the n-type ohmic layer 45. In this manner, the semiconductor device according to the embodiment is manufactured.

### Effects of the Embodiment Will Be Described Below

In the embodiment, a part of carbon atoms in the SiC substrate 20 is also released as carbon dioxide or carbon monoxide by implanting oxygen into the SiC substrate 20. Thereby, the implanted phosphorus atoms are more likely to form bond with silicon atoms, and the activation rate of the phosphorus atoms is improved. As a result, the resistivity of the n-type ohmic layer 45 decreases, and the resistance between the n-type ohmic layer 45 and the conductive member 28 is reduced.

Although an example is shown in the embodiment in which oxygen is ion-implanted in the step shown in FIG. 5C after phosphorus is ion-implanted in the step shown in FIG. 5B, these steps are reversible, i.e. the phosphorus ions may be implanted after the oxygen ion implantation. The V group element to be ion-implanted is not limited to phosphorus, and may be nitrogen or arsenic or the like.

In the embodiment, the configuration of manufacturing apparatuses, the manufacturing method for the semiconductor device, and the effects thereof other than that described above are same as those in the first embodiment.

The aforementioned first embodiment and the second embodiment may be implemented in combination. For example, both the p-type ohmic layer 25 and the n-type ohmic layer 45 can be formed using one manufacturing apparatus 1 in which the ion source 11 is designed so as to implant the group III element, the group V element, and oxygen.

According to the embodiments described above, it is possible to achieve the manufacturing method and the manufacturing apparatus capable of providing a semiconductor device with an ohmic connection of low resistance.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device, the method comprising:
introducing a group III element to a part of a substrate containing silicon and carbon;
introducing oxygen into the part of the substrate; and
heating the substrate after introducing the Group III element and the oxygen.

2. The method according to claim 1, wherein the group III element is aluminum or boron.

3. The method according to claim 1, wherein a dose amount of the oxygen is not less than 0.1 times and not more than 1 time a dose amount of the group III element.

4. The method according to claim 1, wherein the introducing the Group III element and the introducing the oxygen are performed under heating the substrate in a temperature range of not less than 250° C. and not more than 500° C.

5. The method according to claim 1, wherein a heating temperature in the heating substrate is not less than 1700° C. and not more than 1900° C.

6. The method according to claim 1, further comprising:
forming a conductive member on the part of the substrate with an ohmic connection between the conductive member and the part of the substrate.

7. A method for manufacturing a semiconductor device, the method comprising:
introducing a group V element to a part of a substrate containing silicon and carbon;
introducing oxygen into the part of the substrate; and
heating the substrate after introducing the group V element and the oxygen.

8. The method according to claim 7, wherein a heating temperature in the heating substrate is not less than 1700° C. and not more than 1900° C.

9. The method according to claim 7, further comprising:
forming a conductive member on the part of the substrate with an ohmic connection between the conductive member and the part of the substrate.

10. An apparatus for manufacturing a semiconductor device, the apparatus comprising:
an ion source for generating an ion of a group III element or a group V element, and an ion of oxygen;
a mass analyzer for selecting each of the ions;
an accelerator for accelerating the ions; and
a chamber for housing a material, the ions being injected into the material.

11. The apparatus according to claim 10, wherein the material contains silicon and carbon.

12. The apparatus according to claim 10, further comprising a heater for heating the material.

13. The apparatus according to claim 10, wherein the ion source generates an ion of a group III element and an ion of oxygen.

14. The apparatus according to claim 10, wherein the ion source generates an ion of a group V element and an ion of oxygen.
